(19) United States
(12) Patent Application Publication
(10) Pub. No.: US 2025/0359242 A1
(43) Pub. Date: Nov. 20, 2025

(54) SEMICONDUCTOR DEVICE WITH BACKSIDE VIA

(71) Applicants: TAIWAN SEMICONDUCTOR MANUFACTURING COMPANY, LTD., Hsinchu (TW); NATIONAL TAIWAN UNIVERSITY, Taipei (TW)

(72) Inventors: Hsin-Cheng LIN, Taipei City (TW); Chien-Te TU, Hsinchu City (TW); Chin-Yu LIU, Taipei City (TW); Chun-Yi CHENG, Taipei City (TW); Chee-Wee LIU, Taipei City (TW)

(73) Assignees: TAIWAN SEMICONDUCTOR MANUFACTURING COMPANY, LTD., Hsinchu (TW); NATIONAL TAIWAN UNIVERSITY, Taipei (TW)

(21) Appl. No.: 18/666,769

(22) Filed: May 16, 2024

(51) Int. Cl. H01L 29/40; H01L 29/06; H01L 29/417; H01L 29/423; H01L 29/45; H01L 29/66; H01L 29/775; H01L 29/786

(52) U.S. Cl. CPC H10D 64/01; H10D 30/014; H10D 30/43; H10D 30/6735; H10D 30/6757; H10D 62/121; H10D 62/83; H10D 64/251; H10D 64/254; H10D 64/258; H10D 64/62

(57) ABSTRACT

A method includes following steps. A bottom sacrificial layer is over a substrate. An epitaxial structure is formed over the bottom sacrificial layer. The epitaxial structure is etched such that the bottom sacrificial layer is exposed. An epitaxial source/drain region is formed on the exposed bottom sacrificial layer. The bottom sacrificial layer is removed from a bottom surface of the epitaxial source/drain region. After removing the bottom sacrificial layer, a source/drain contact is formed wrapping around the bottom surface, a top surface, and opposite sidewalls of the epitaxial source/drain region.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of an intermediate stage in manufacturing an IC structure, and FIG. 1B is a cross-sectional view obtained from cut A-A′ in FIG. 1A.

FIG. 2A is a top view of an intermediate stage in manufacturing of an IC structure, and FIG. 2B is a cross-sectional view obtained from cut A-A′ in FIG. 2A.

FIG. 3A is a top view of an intermediate stage in manufacturing of an IC structure, and FIG. 3B is a cross-sectional view obtained from cut A-A′ in FIG. 3A.

FIG. 4A is a top view of an intermediate stage in manufacturing of an IC structure, FIG. 4B is a cross-sectional view obtained from cut A-A′ in FIG. 4A, and FIG. 4C is a cross-sectional view obtained from cut B-B′ in FIG. 4A.

FIG. 5A is a top view of an intermediate stage in manufacturing of an IC structure, FIG. 5B is a cross-sectional view obtained from cut A-A′ in FIG. 5A, and FIG. 5C is a cross-sectional view obtained from cut B-B′ in FIG. 5A.

FIG. 6A is a top view of an intermediate stage in manufacturing of an IC structure, and FIG. 6B is a cross-sectional view obtained from cut A-A′ in FIG. 6A.

FIG. 7A is a top view of an intermediate stage in manufacturing of an IC structure, and FIG. 7B is a cross-sectional view obtained from cut A-A′ in FIG. 7A.

FIG. 8A is a top view of an intermediate stage in manufacturing of an IC structure, and FIG. 8B is a cross-sectional view obtained from cut A-A′ in FIG. 8A.

FIG. 9A is a top view of an intermediate stage in manufacturing of an IC structure, FIG. 9B is a cross-sectional view obtained from cut A-A′ in FIG. 9A, and FIG. 9C is a cross-sectional view obtained from cut B-B′ in FIG. 9A.

FIG. 10A is a top view of an intermediate stage in manufacturing of an IC structure, FIG. 10B is a cross-sectional view obtained from cut A-A′ in FIG. 10A, and FIG. 10C is a cross-sectional view obtained from cut B-B′ in FIG. 10A.

FIG. 11A is a top view of an intermediate stage in manufacturing of an IC structure, FIG. 11B is a cross-sectional view obtained from cut A-A′ in FIG. 11A, and FIG. 11C is a cross-sectional view obtained from cut B-B′ in FIG. 11A.

FIG. 12A is a top view of an intermediate stage in manufacturing of an IC structure, FIG. 12B is a cross-sectional view obtained from cut A-A′ in FIG. 12A, and FIG. 12C is a cross-sectional view obtained from cut B-B′ in FIG. 12A.

FIG. 12D is a cross-sectional view obtained from cut B-B′ in FIG. 12A, in accordance with some other embodiments.

FIG. 13A is a plan view of an intermediate stage in manufacturing of an IC structure, FIG. 13B is a cross-sectional view obtained from cut A-A′ in FIG. 13A, and FIG. 13C is a cross-sectional view obtained from cut B-B′ in FIG. 13A.

FIG. 13D is a cross-sectional view obtained from cut B-B′ in FIG. 13A, in accordance with some other embodiments.

FIG. 14 is graph illustrating current-voltage (I-V) simulation results of transistors with different contact schemes.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The present disclosure is generally related to integrated circuit structures and methods of forming the same, and more particularly to fabricating gate-all-around (GAA) transistors with a backside via below a source region and/or a drain region of the GAA transistors. It is also noted that the present disclosure presents embodiments in the form of multi-gate transistors. Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

As scales of the fin width in fin field effect transistors (FinFET) decreases, channel width variations might cause mobility loss. GAA transistors, such as nanosheet transistors are being studied as an alternative to fin field effect transistors. In a nanosheet transistor, the gate of the transistor is made all around the channel (e.g., a nanosheet channel or a nanowire channel) such that the channel is surrounded or encapsulated by the gate. Such a transistor has the advantage of improving the electrostatic control of the channel by the gate, which also mitigates leakage currents.

In order to create more routing space for an integrated circuit (IC) structure having a large number of GAA transistors, backside interconnects (e.g., backside metal lines) connected to backside surfaces of source/drain regions of GAA transistors using backside metal vias are being studied as an alternative to front-side interconnects formed on front-side of source/drain regions of transistors. Although backside interconnect techniques result in significant improvement in scaling down the IC footprint, they may not be satisfactory in all aspects. For example, the GAA transistors with backside vias may suffer from increased contact resistance, because the backside silicide regions are formed at a low temperature to prevent damages on front-end-of-line (FEOL) devices (e.g., GAA transistors). Therefore, the present disclosure in various embodiments provides full-wraparound source/drain contacts that wrap around all sides of epitaxial source/drain regions, which in turn reduces the contact resistance with the backside vias.

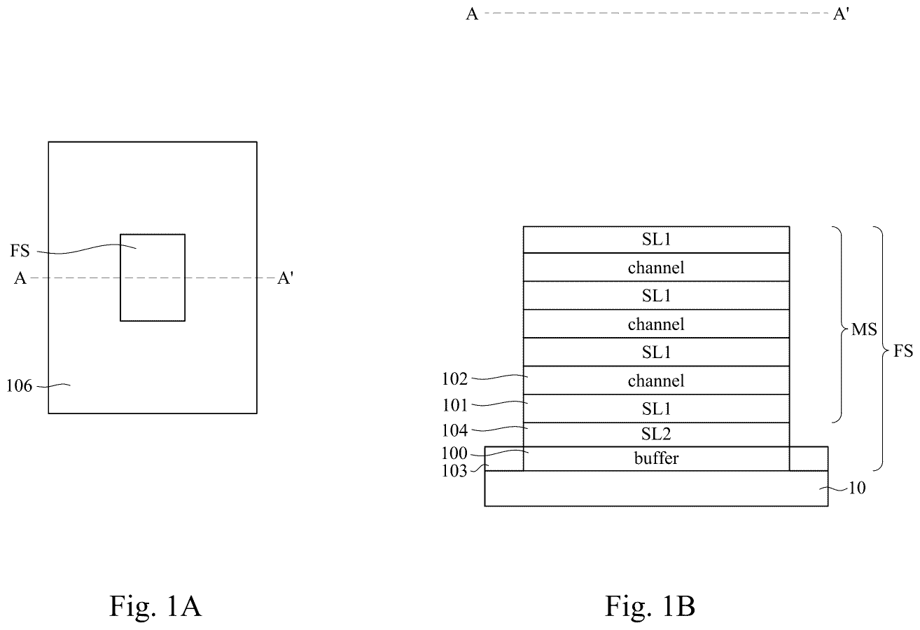

FIGS. 1A-13D are top views and cross-sectional views of intermediate stages in the manufacturing of an IC structure having a GAA device coupled to a backside metal via, in accordance with some embodiments of the present disclosure. It is understood that additional operations can be provided before, during, and after processes shown by FIGS. 1A-13D, and some of the operations described below can be replaced or eliminated, for additional embodiments of the method. The order of the operations/processes may be interchangeable.

FIG. 1A is a top view of an intermediate stage in manufacturing an IC structure, and FIG. 1B is a cross-sectional view obtained from cut A-A′ in FIG. 1A. In FIGS. 1A and 1B, a semiconductor substrate 10 is illustrated. In some embodiments, the substrate 10 may be a semiconductor substrate, such as a bulk semiconductor substrate, a semiconductor-on-insulator (SOI) substrate, a multi-layered or gradient substrate, or the like. The substrate 10 may include a semiconductor material, such as an elemental semiconductor including Si and Ge; a compound or alloy semiconductor including SiC, SiGe, GeSn, GaAs, GaP, GaAsP, AlInAs, AlGaAs, GaInAs, InAs, GaInP, InP, InSb, GaInAsP; a combination thereof, or the like. The substrate 10 may be doped or substantially un-doped. In a specific example, the substrate 10 is a bulk silicon substrate, which may be a wafer.

The substrate 10 may include in its surface region, one or more buffer layers 100 (denoted as “buffer”). The buffer layer 100 can serve to change the lattice constant from that of the substrate 10 to that of a subsequently formed multilayer stack. The buffer layer 100 may be formed from epitaxially grown single crystalline semiconductor materials such as, but not limited to Ge, GeSn, SiGe, GaAs, InSb, GaP, GaSb, InAlAs, InGaAs, GaSbP, GaAsSb, GaN, GaP, and InP.

FIGS. 1A and 1B further illustrate a bottom sacrificial layer (denoted as “SL2”) 104 formed over the buffer layer 100 and a multilayer epitaxial stack MS formed over the bottom sacrificial layer 104. The multilayer epitaxial stack MS includes one or more first semiconductor layers 101 alternating with one or more second semiconductor layers 102. For purposes of illustration and as discussed in greater detail below, the first semiconductor layers 101 serve as sacrificial layers denoted as “SL1” that will be removed and the second semiconductor layers 102 serve as channel layers denoted as “channel” that will be patterned to form channel regions of GAA transistors.

In some embodiments, the bottom sacrificial layer 104 is formed of a material having a high-etch selectivity to the first and second semiconductor layers 101, 102. As such, etching operations performed to the first and second semiconductor layers 101, 102 will result in no or negligible etch amount in the bottom sacrificial layer 104, thus resulting in no or negligible consumption to the bottom sacrificial layer 104. In some embodiments, the bottom sacrificial layer 104 has a thickness different from a thickness of the first semiconductor layers 101 and/or a thickness of the second semiconductor layers 102, because the bottom sacrificial layer 104 serves for a different function than the first and second semiconductor layers 101, 102. In particular, the bottom sacrificial layer 104 will be removed and replaced with a source/drain contact metal in subsequent processing, and thus the thickness of the bottom sacrificial layer 104 depends on a desired size of the source/drain contact. In some embodiments, the thickness of the bottom sacrificial layer 104 is greater than the thickness of the first semiconductor layers 101 and/or the thickness of the second semiconductor layers 102, in some embodiments where the subsequently formed contact thickness is greater than GAA channel thicknesses (i.e., thicknesses of second semiconductor layers 102) and sheet-to-sheet distances (i.e., thickness of first semiconductor layers 101). In some embodiments, the bottom sacrificial layer 104 has a thickness greater than about 5 nm, such as in a range from about 5 nm to about 100 nm.

In some embodiments, the bottom sacrificial layer 104 is a dielectric material such as silicon oxycarbon nitride (SiOCN), which is more suitable for epitaxially growing an epitaxial material than silicon oxide (SiO₂). In some embodiments, a bottommost semiconductor layer 101 of the multilayer stack MS may be grown on the SiOCN layer using techniques such as chemical vapor deposition (CVD) or molecular beam epitaxy (MBE). In some embodiments, prior to the deposition of the bottommost semiconductor layer 101, the SiOCN layer undergoes surface preparation, which may include cleaning with organic solvents, etching, and annealing, to provide surface substantially free of contaminants and conducive to epitaxial growth.

In some embodiments, the number of second semiconductor layers is from 3 to 100. In some embodiments, the first and second semiconductor layers 101 and 102 are made of different semiconductor materials selected from the group consisting of Si, Ge, Sn, Si₁₋ₓGeₓ, Ge_{1-y}Sn_{y}, Si_{1-x-y}GeₓSn_{y}, Group III-V compound, and combinations thereof. In some embodiments, the first and second semiconductor layers 101 and 102 are formed by epitaxy. In some embodiments, the SiGe is Si₁₋ₓGeₓ, where 0<x<1. In some embodiments, the sacrificial layer 101 is formed of an oxide material.

In some embodiments, the first semiconductor layers 101 are formed of boron-doped germanium (Ge:B) without silicon, and the second semiconductor layers 102 is formed of silicon germanium, e.g., Ge_{0.9}Si_{0.1}, which includes germanium atomic percentage greater than silicon atomic percentage. In some embodiments where the first semiconductor layers 101 are formed of boron-doped germanium (Ge:B), in-situ doping during the epitaxial growth of the first semiconductor layers 101 can be utilized to introduce dopants, such as boron, into first the semiconductor layers 101.

The first semiconductor layers 101 and the second semiconductor layers 102 may be formed by one or more epitaxy or epitaxial (epi) processes. The epitaxy processes include CVD deposition techniques (e.g., vapor-phase epitaxy (VPE) and/or ultra-high vacuum CVD (UHV-CVD)), molecular beam epitaxy (MBE), and/or other suitable processes. Thickness of the sacrificial layers 101 depends on a target distance (also called sheet-to-sheet distance if the channel layers 102 are patterned into nanosheets) between the channel layers 102 and a target distance between the bottommost channel layer 102 and the bottom sacrificial layer 104. For example, the thickness of the sacrificial layers 101 is in a range from about 3 nm to about 200 nm. Thickness of the channel layers 102 depends on a target thickness of transistor channels (also called nanosheet thickness if the channel layers 102 are patterned into nanosheets). For example, the thickness of the channel layers 102 is in a range from about 1 nm to about 50 nm. In some embodiments, a thickness of each of the sacrificial layers 101 is different from (e.g., greater than) a thickness of each of the channel layers 102, which allows for a sheet-to-sheet distance different from (e.g., greater than) a sheet thickness. In some embodiments, a first one of the channel layers 102 has a different thickness than a second one of the channel layers 102, which allows for nanosheets with different thicknesses coexisting in a GAA transistor. In some embodiments, a first one of the sacrificial layers 101 has a different thickness than a second one of the sacrificial layers 101, which allows for different sheet-to-sheet distances coexisting in a GAA transistor.

After the epitaxial growth process of the multilayer stack MS is complete, a patterning process is performed on the multilayer stack MS, the bottom sacrificial layer 104, and the buffer layer 100 to form a fin structure FS protruding from the substrate 10, as illustrated in FIGS. 1A and 1B. In some embodiments, the patterning process comprises a photolithography process for forming a patterned mask, followed by one or more etching processes using the patterned mask as an etch mask. The one or more etching processes may include wet etching processes, anisotropic dry etching processes, or combinations thereof, and may use one or more etchants that etch the multilayer stack MS, the bottom sacrificial layer 104 and the buffer layer 100 at a faster etch rate than it etches the patterned mask. Although the fin structure FS illustrated in FIG. 1B has vertical sidewalls, the etching process may lead to tapered sidewalls in some other embodiments.

Once the fin structure FS has been formed, shallow trench isolation (STI) regions 103 (interchangeably referred to as isolation insulation layer) are formed around a lower portion of the fin structure FS are illustrated in FIGS. 1A and 1B. STI regions 103 may be formed by depositing one or more dielectric materials (e.g., silicon oxide) to completely fill the trenches around the fin structures FS and then recessing the top surface of the dielectric materials. The dielectric materials of the STI regions 103 may be deposited using a high density plasma chemical vapor deposition (HDP-CVD), a low-pressure CVD (LPCVD), sub-atmospheric CVD (SACVD), a flowable CVD (FCVD), spin-on coating, and/or the like, or a combination thereof. After the deposition, an anneal process or a curing process may be performed. In some cases, the STI regions 103 may include a liner such as, for example, a thermal oxide liner grown by oxidizing the silicon surface or silicon germanium surface of the fin structure FS and the substrate 10. The recess process may use, for example, a planarization process (e.g., a chemical mechanical polish (CMP)) followed by a selective etch process (e.g., a wet etch, or dry etch, or a combination thereof) that may recess the top surface of the dielectric materials in the STI regions 103 such that an upper portion of the fin structure FS protrudes from surrounding insulating STI regions 103.

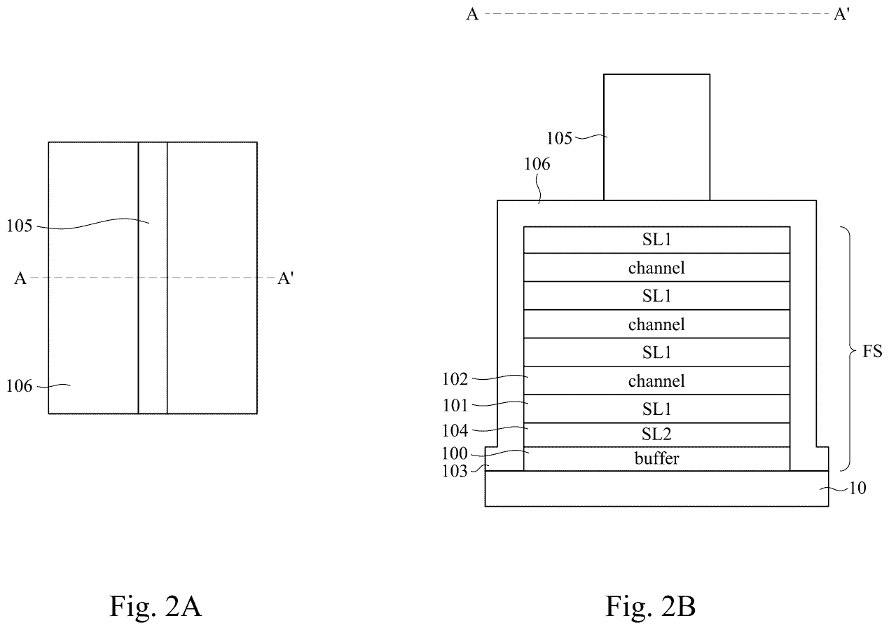

FIG. 2A is a top view of an intermediate stage in manufacturing of an IC structure, and FIG. 2B is a cross-sectional view obtained from cut A-A′ in FIG. 2A. In FIGS. 2A and 2B, a sacrificial dielectric layer 106 is blanket deposited over the substrate 10, and then a dummy gate structure 105 is formed across the fin structure FS. In some embodiments, the dummy gate structure 105 has a longitudinal axis perpendicular to the longitudinal axis of the fin structure FS. The sacrificial dielectric layer 106 may be, for example, silicon oxide, silicon nitride, a combination thereof, or the like, and may be deposited or thermally grown according to acceptable techniques. The dummy gate structure 105 may be a conductive or non-conductive material and may be selected from a group including amorphous silicon, polycrystalline-silicon (polysilicon), polycrystalline silicon-germanium (poly-SiGe), metallic nitrides, metallic silicides, metallic oxides, and metals. The dummy gate structure 105 is formed by, for example, depositing a layer of dummy gate material over the sacrificial dielectric layer 106, followed by patterning the layer of dummy gate material into separate dummy gate structures 105 by using suitable photolithography and etching techniques.

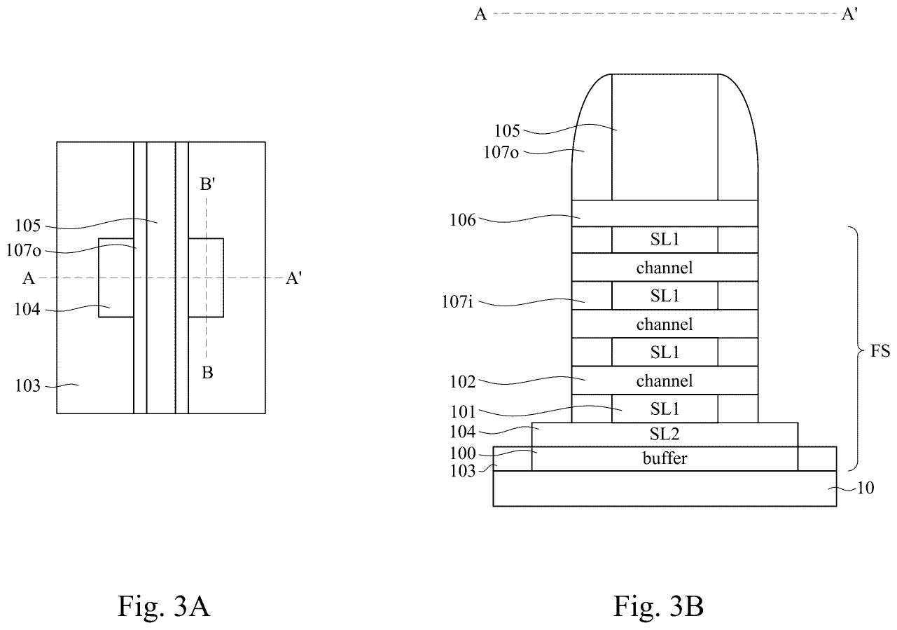

FIG. 3A is a top view of an intermediate stage in manufacturing of an IC structure, and FIG. 3B is a cross-sectional view obtained from cut A-A′ in FIG. 3A. In FIGS. 3A and 3B, gate spacers 1070 are formed on sidewalls of the dummy gate structure 105. In some embodiments of the spacer formation step, a spacer material layer is deposited on the substrate 10. The spacer material layer may be a conformal layer that is subsequently etched back to form gate sidewall spacers. In the illustrated embodiment, a spacer material layer is disposed conformally on top and sidewalls of the dummy gate structure 105. The spacer material layer may include a dielectric material such as silicon oxide, silicon nitride, silicon carbide, silicon oxynitride, SiCN films, silicon oxycarbide, SiOCN films, and/or combinations thereof. The spacer material layer may be formed by depositing a dielectric material over the dummy gate structure 308 using processes such as, CVD process, a subatmospheric CVD (SACVD) process, a flowable CVD process, an ALD process, a PVD process, or other suitable process. An anisotropic etching process is then performed on the deposited spacer material layer to remove horizontal portions of the spacer material layer. Vertical portions of the spacer material layer on sidewalls of the dummy gate structure 105 may remain, forming gate sidewall spacers, which is denoted as the gate spacers 1070, for the sake of simplicity.

After forming the gate spacers 1070, exposed portions of the sacrificial dielectric layer 106 and underlying portions of the fin structure FS that extend laterally beyond the dummy gate structure 105 and gate spacers 1070 are removed, for example, in an anisotropic etch step until the bottom sacrificial layer 104 is exposed. In some embodiments, the etching is performed using an etchant that attacks fin structure FS, and hardly attacks the dummy gate structure 105, gate spacers 1070 and the bottom sacrificial layer 104. Stated differently, the dummy gate structure 105, gate spacers 1070 and the bottom sacrificial layer 104 have higher etch resistance to the etching process than that of the fin structure FS. Accordingly, in the etching step, the heights of dummy gate structure 105 and gate spacers 1070, and the thickness of the sacrificial layer 107 may be not reduced.

After etching the fin structure FS, sidewalls of the first semiconductor layers 101 of the fin structure FS are etched to form sidewall recesses R1 between corresponding second semiconductor layers 102. Although sidewalls of the first semiconductor layers 101 in recesses R1 are illustrated as being straight in FIG. 3B, the sidewalls may be concave or convex. The sidewalls may be etched using isotropic etching processes, such as wet etching or the like. In some embodiments in which the first semiconductor layers 101 include, e.g., Ge:B, and the second semiconductor layers 102 include, e.g., SiGe having a higher silicon content than the first semiconductor layers 101, a dry etch process with tetramethylammonium hydroxide (TMAH), ammonium hydroxide (NH₄OH), or the like may be used to etch sidewalls of the first semiconductor layers 101.

After the first semiconductor layers 101 are laterally recessed, inner spacers 107i are formed in the sidewall recesses R1. The inner spacers 107i act as isolation features between subsequently formed source/drain regions and gate structure. As will be discussed in greater detail below, source/drain regions will be formed on the exposed surface of the bottom sacrificial layer 104, and the first semiconductor layers 101 will be replaced with a high-k/metal gate structure in following processing.

Inner spacers 107i are formed from an inner spacer layer that is deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 107i. Although outer sidewalls of the inner spacers 107i are illustrated as being flush with sidewalls of the channel layers 102, the outer sidewalls of the inner spacers 107i may extend beyond or be recessed from sidewalls of the channel layers 102. Moreover, although the outer sidewalls of the inner spacers 107i are illustrated as being straight in FIG. 3B, the outer sidewalls of the inner spacers 107i may be concave or convex. The inner spacer layer may be etched by an anisotropic etching process, such as RIE, NBE, or the like. The inner spacers 107i may be used to prevent damage to subsequently formed source/drain regions caused by subsequent etching processes, such as etching processes used to form gate structures.

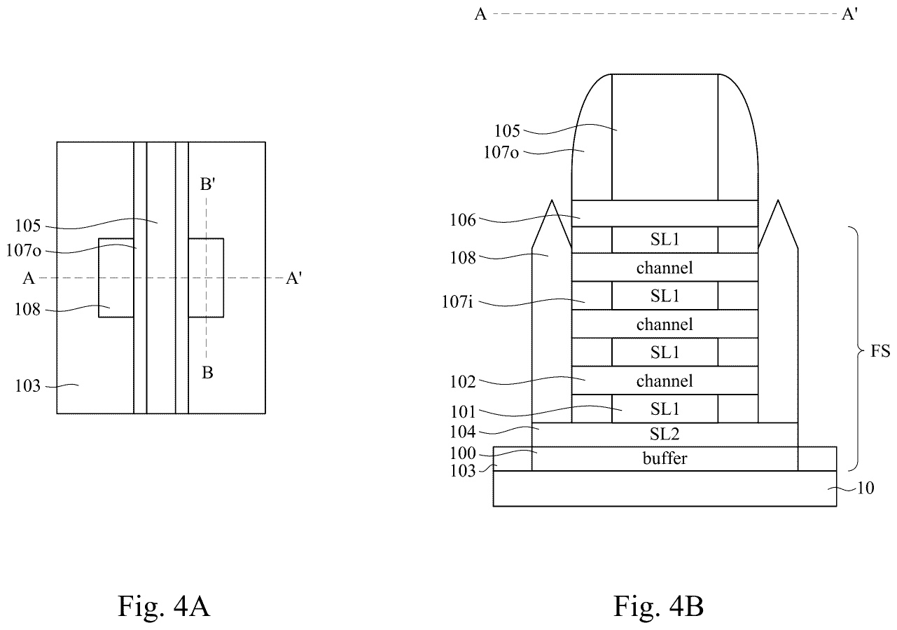

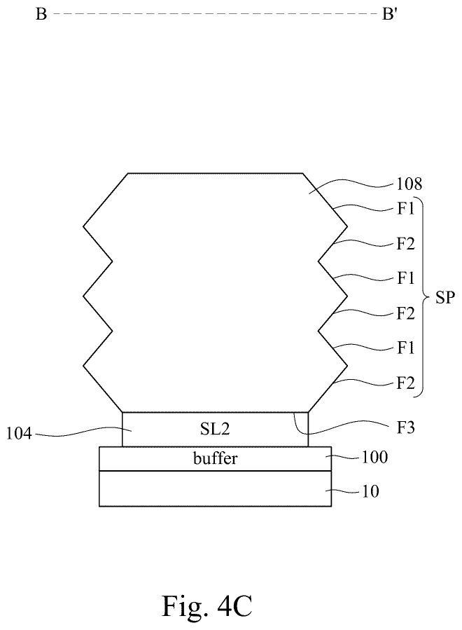

FIG. 4A is a top view of an intermediate stage in manufacturing of an IC structure, FIG. 4B is a cross-sectional view obtained from cut A-A′ in FIG. 4A, and FIG. 4C is a cross-sectional view obtained from cut B-B′ in FIG. 4A. In FIGS. 4A-4C, epitaxial source/drain regions 108 are formed on the exposed surface of the bottom sacrificial layer 104 and at opposite sides of the channel layers 102. In some embodiments, the source/drain regions 108 may exert stress on the channel layers 102, thereby improving device performance. As illustrated in FIG. 4B, the dummy gate structure 105 is disposed between respective neighboring pairs of the epitaxial source/drain regions 108. In some embodiments, the gate spacers 1070 are used to separate the epitaxial source/drain regions 108 from the dummy gate structures 105, and the inner spacers 107i are used to separate the epitaxial source/drain regions 108 from the first semiconductor layers 101 by an appropriate lateral distance so that the epitaxial source/drain regions 108 do not short out with the subsequently formed gate structure.

In some embodiments, the epitaxial source/drain regions 108 include Si, Ge, Sn, Si₁₋ₓGeₓ, Si_{1-x-y}GeₓSn_{y}, or the like. For example, the epitaxial source/drain regions 108 may include silicon germanium, e.g., Si_{0.1}Ge_{0.9}. In some embodiments, the epitaxial source/drain regions 108 may include any acceptable material appropriate for n-type FETs. For example, if the channel layers 102 are silicon, the epitaxial source/drain regions 108 may include materials exerting a tensile strain on the channel layers 102, such as silicon carbide, phosphorous doped silicon carbide, silicon phosphide, or the like. In some embodiments, the epitaxial source/drain regions 108 may include any acceptable material appropriate for p-type FETs. For example, if the channel layers 102 are silicon, the epitaxial source/drain regions 108 may comprise materials exerting a compressive strain on the channel layers 102, such as silicon germanium, boron doped silicon germanium, germanium, germanium tin, or the like.

The epitaxial source/drain regions 108 may be implanted with dopants to form source/drain regions, followed by an anneal process. The source/drain regions may have an impurity concentration of between about 1×10¹⁶ atoms/cm³ and about 1×10²³ atoms/cm³. In some embodiments, the dopants are, for example, boron for an n-type FET and phosphorus for a p-type FET. The n-type and/or p-type impurities for source/drain regions may be any of the impurities previously discussed. In some embodiments, the epitaxial source/drain regions 108 may be in situ doped during growth.

In some embodiments, the epitaxial source/drain regions 108 may have surfaces raised from respective the upper surface of the upper channel layer 102 and may have facets. In some embodiments, as illustrated in FIG. 4C, the epitaxial source/drain regions 108 each have a zigzag-shaped sidewall profile SP including a plurality of up-slant facets F1 alternating with a plurality of down-slant facets F2. The up-slant facets F1 face upwards away from the substrate 10, and the down-slant facets F2 face towards the substrate 10.

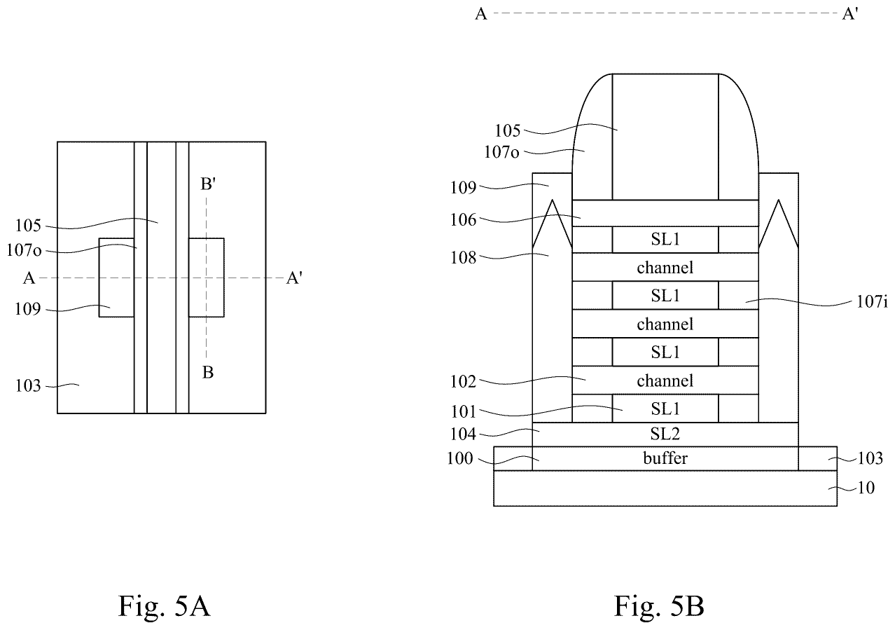

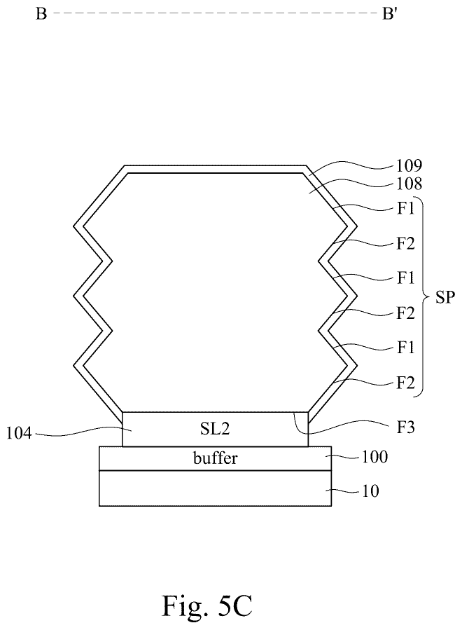

FIG. 5A is a top view of an intermediate stage in manufacturing of an IC structure, FIG. 5B is a cross-sectional view obtained from cut A-A′ in FIG. 5A, and FIG. 5C is a cross-sectional view obtained from cut B-B′ in FIG. 5A. In FIGS. 5A-5C, a self-aligned silicidation process may be performed on epitaxial source/drain regions 108 to form a metal silicide layer 109 on exposed surfaces of the epitaxial source/drain regions 108. The metal silicide layer 109 can serve to reduce the contact resistance between the source/drain regions 108 and the subsequently formed source/drain contacts. In the self-aligned process, a thin layer of a metal, such as nickel (Ni), cobalt (Co), or titanium (Ti), is blanket deposited over the substrate 10, specifically over exposed surfaces of epitaxial source/drain regions 108. The substrate 10 with the metal layer is then subjected to one or more annealing steps, for example at a temperature of 600° C. or higher. This annealing process causes the metal to selectively react with the exposed semiconductor material (e.g., silicon) of the epitaxial source/drain regions 108, thereby forming a metal silicide layer 109 (e.g., TiSi, NiSi or the like), while the metal over the dielectric materials remains unreacted. The unreacted metal can then be selectively removed using a wet or dry etching process, leaving the metal silicide layers 109 respectively on the epitaxial source/drain regions 108.

In some embodiments, as illustrated in FIG. 5C, the bottom surface F3 of the epitaxial source/drain region 108 is entirely in contact with the bottom sacrificial layer 104, and thus the bottom surface F3 of the epitaxial source/drain region 108 is free of coverage by the metal silicide layer 109. In some embodiments, a bottom end of the metal silicide layer 109 may be in contact with a sidewall surface of the bottom sacrificial layer 104. In some embodiments, as illustrated in FIG. 5C, the metal silicide layer 109 is conformal to the epitaxial source/drain region 108, and thus the metal silicide layer 109 also has a zigzag-shaped sidewall profile inheriting the zigzag-shaped sidewall profile of the epitaxial source/drain region 108. In greater detail, the metal silicide layer 109 includes a plurality of up-slant facets alternating with a plurality of down-slant facets.

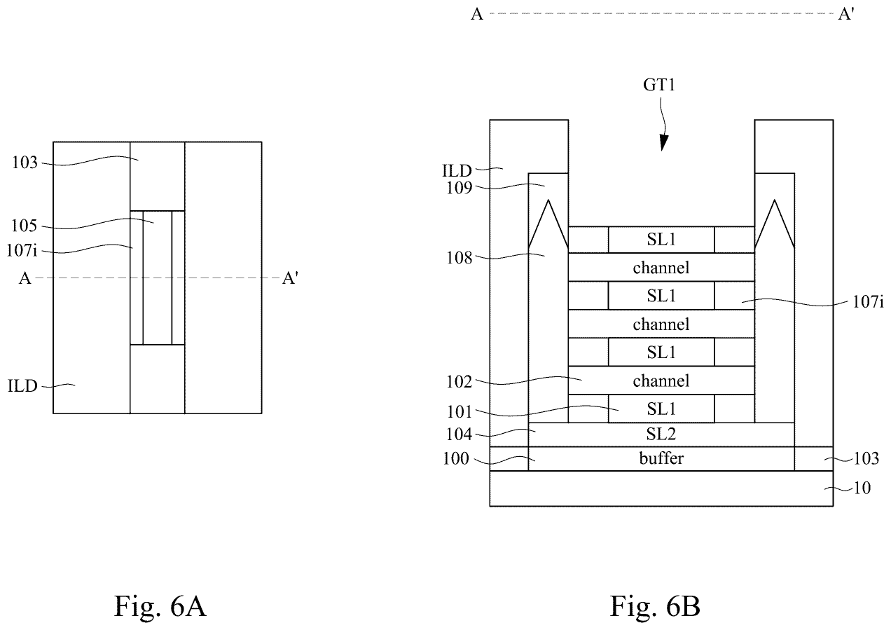

FIG. 6A is a top view of an intermediate stage in manufacturing of an IC structure, and FIG. 6B is a cross-sectional view obtained from cut A-A′ in FIG. 6A. In FIGS. 6A and 6B, the dummy gate structure 105, the gate spacers 1070, and the sacrificial dielectric layer 106 are removed in one or more etching steps, so that a gate trench GT1 is formed between the epitaxial source/drain regions 108. In some embodiments, the dummy gate structure 105, gate spacers 1070 and the sacrificial dielectric layer 106 are removed by an anisotropic dry etch process. For example, the etching process may include a dry etch process using reaction gas(es) that selectively etch the dummy gate structure 105 and the gat spacers 1070 at a faster rate than etching the inner spacers 107i. During the removal, the sacrificial dielectric layer 106 may be used as an etch stop layer when the dummy gate structure 105 and/or gate spacers 1070 are etched. The sacrificial dielectric layer 106 may then be removed after the removal of the dummy gate structure 105. In some embodiments, prior to forming the gate trench GT1, a dielectric layer, e.g., interlayer dielectric layer ILD may be formed over the metal silicide layers 109 to protect the metal silicide layers 109 and underlying epitaxial source/drain regions 108 against the etching operation(s) for forming the gate trench GT1. For example, the interlayer dielectric layer ILD can be formed by depositing one or more dielectric materials (e.g., silicon oxide) over the substrate 10, followed by performing a CMP process on the interlayer dielectric layer ILD to expose the dummy gate structure 105.

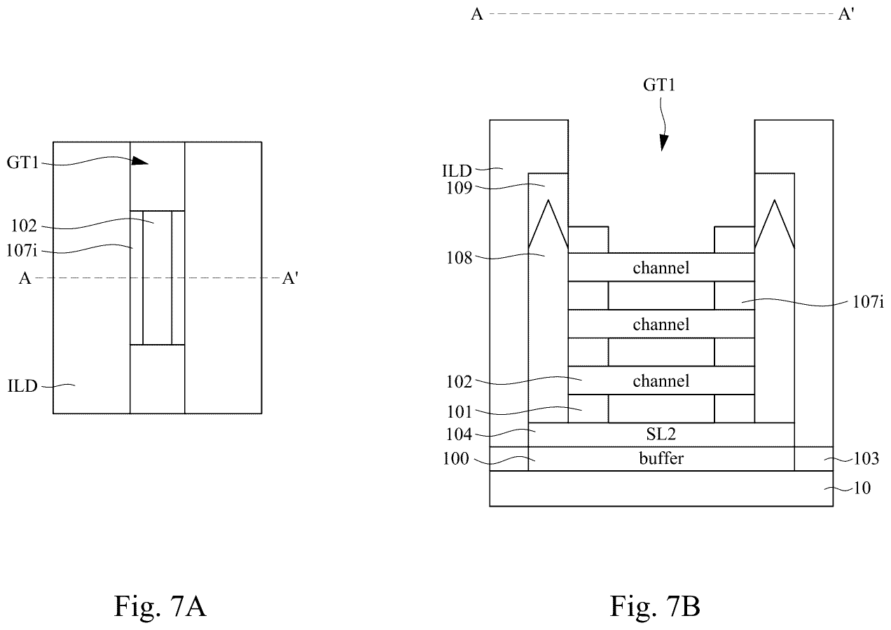

FIG. 7A is a top view of an intermediate stage in manufacturing of an IC structure, and FIG. 7B is a cross-sectional view obtained from cut A-A′ in FIG. 7A. In FIGS. 7A and 7B, the sacrificial layers 101 exposed in the gate trench GT1 are removed by an isotropic etching process such as wet etching or the like using etchants which are selective to the materials of the sacrificial layers 101. Stated differently, the sacrificial layers 101 are removed by using a selective etching process that etches the sacrificial layers 101 at a faster etch rate than it etches the channel layers 102 and the bottom sacrificial layer 104, thus forming spaces between the channel layers 102 (also referred to as sheet-to-sheet spaces if the channel layers 102 are nanosheets). This step can be referred to as a channel release process. At this interim processing step, the spaces between channel layers 102 may be filled with ambient environment conditions (e.g., air, nitrogen, etc). In some embodiments, the channel layers 102 can be referred to as nanosheets, nanowires, nanoslabs, nanorings having nano-scale size (e.g., a few nanometers), depending on their geometry. In some embodiments, the channel layers 102 (also referred to as nanosheets or nanostructures) each have a thickness in a range from about 1 nm to about 50 nm, and a width or diameter in a range from about 1 nm to about 50 nm. In some embodiments, the cross-section profile of the channel layers 102 can be rectangular, square, circular, elliptical, diamond, etc., with or without rounded corners.

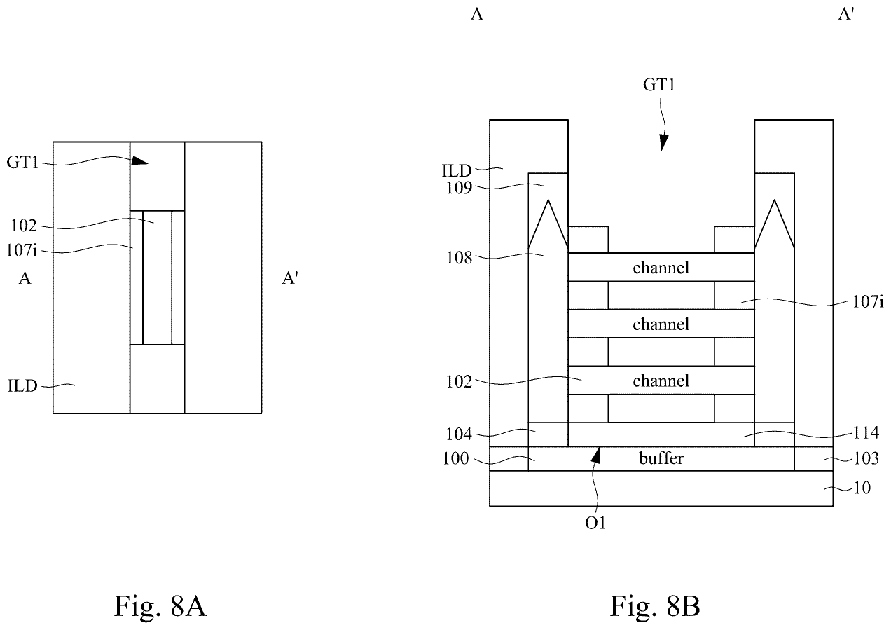

FIG. 8A is a top view of an intermediate stage in manufacturing of an IC structure, and FIG. 8B is a cross-sectional view obtained from cut A-A′ in FIG. 8A. In FIGS. 8A and 8B, a portion of the sacrificial layer 104 exposed in the gate trench GT1 is replaced with a dielectric structure 114, while leaving a remaining portion of the sacrificial layer 104 below the epitaxial source/drain regions 108. The dielectric structure 114 is formed of a different material than the sacrificial layer 104 and thus has an etch selectivity to the sacrificial layer 104. Therefore, the dielectric structure 114 can serve to define a boundary of source/drain contact that will replace the remaining portion of the sacrificial layer 104 in subsequent processing. In some embodiments, the dielectric structure 114 is an oxide material, e.g., silicon oxide or other suitable oxide materials. In some embodiments, the dielectric structure 114 is formed by, for example, etching an opening O1 in the sacrificial layer 104 in the gate trench GT1, depositing an oxide material into the opening O1 in the sacrificial layer 104, followed by selectively etching back the oxide material to form the dielectric structure 114 having a top surface not higher than a bottom surface of a bottommost inner spacer 107i.

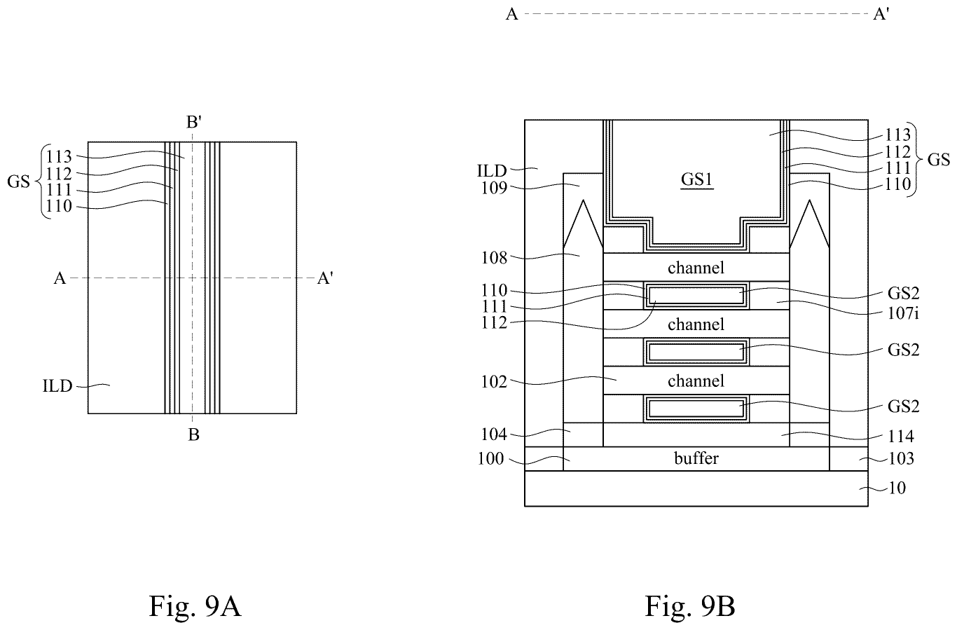

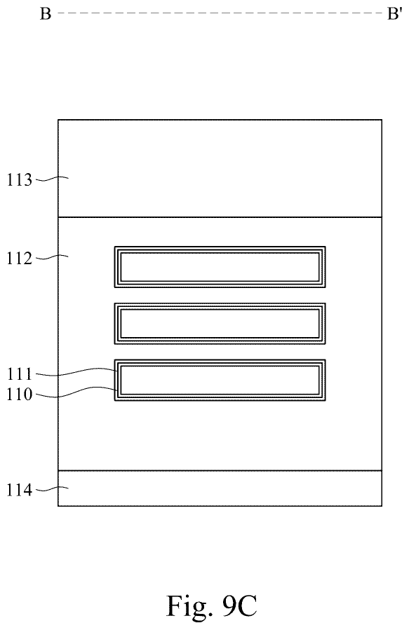

FIG. 9A is a top view of an intermediate stage in manufacturing of an IC structure, FIG. 9B is a cross-sectional view obtained from cut A-A′ in FIG. 9A, and FIG. 9C is a cross-sectional view obtained from cut B-B′ in FIG. 9A. In FIGS. 9A-9C, a replacement gate structure GS is formed in the gate trench GT1 to surround each of the nanosheets 102 suspended in the gate trench GT1. The gate structure GS may be a final gate of a GAA transistor. The final gate structure may be a high-k/metal gate stack, however other compositions are possible. In some embodiments, the gate structure GS forms the gate associated with the multi-channels provided by the plurality of nanosheets 102. For example, high-k/metal gate structure GS is formed within the sheet-to-sheet spaces provided by the release of the nanosheets 102. In various embodiments, the high-k/metal gate structure GS includes an interfacial layer 110 formed around the nanosheets 102, a high-k gate dielectric layer 111 formed around the interfacial layer 110, one or more work function metal layers 112 formed around the high-k gate dielectric layer 111, and a fill metal layer 113 formed around the one or more work function metal layers 112 and filling a remainder of the gate trench GT1. Formation of the high-k/metal gate structure GS may include one or more deposition processes to form various gate materials, followed by an etch back process to remove excessive gate materials, resulting in the high-k/metal gate structure GS having a top surface substantially level with a top surface of the interlayer dielectric layer ILD.

In some embodiments, the interfacial layer 110 is formed of a high-k dielectric material such as aluminum oxide (Al₂O₃) with a dielectric constant of about 9, which is greater than a dielectric constant of silicon oxide (about 3.9). In some embodiments, the high-k dielectric layer 111 is formed of another high-k dielectric material having a dielectric constant greater than that of the interfacial layer 110. For example, the high-k dielectric layer 111 is formed of zirconium oxide (ZrO₂) with a dielectric constant of about 40, titanium oxide (TiO₂) with a dielectric constant of about 95, yttrium oxide (Y₂O₃) with a dielectric constant of about 14 to about 18, tantalum oxide (Ta₂O₅) with a dielectric constant of about 26, or hafnium zirconium oxide (HZO) with a dielectric constant of about 20 to about 45.

In some embodiments, the work function metal layer 112 includes one or more n-type work function metal (N-metal) layers and/or one or more p-type work function metal (P-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal 113 may exemplarily include, but are not limited to, Pt, Ti, TiN, Al, W, WN, Ru, RuO, Ta, Ni, Co, Cu, Ag, Au, or other suitable materials.

As illustrated in FIG. 9B, the gate structure GS includes an upper gate portion GS1 above a topmost nanosheet 102, and a plurality of lower gate portions GS2 respectively in the sheet-to-sheet spaces between corresponding two of the nanosheets 102. In some embodiments, the lower gate portions GS2 may include a different material composition than the upper gate portion GS1. For example, the upper gate portion GS1 includes the fill metal 113 and the lower gate portions GS2 may be free of the fill metal 113. This is because the sheet-to-sheet spaces may be already filled with the work function metal layer 112 prior to depositing the fill metal 113. In some embodiments, the upper gate portion GS1 has a larger width than the lower gate portions GS2. This is because the gate spacers 1070 are removed along with the dummy gate structure 105, while the inner spacers 107i still remain between corresponding nanosheets 102.

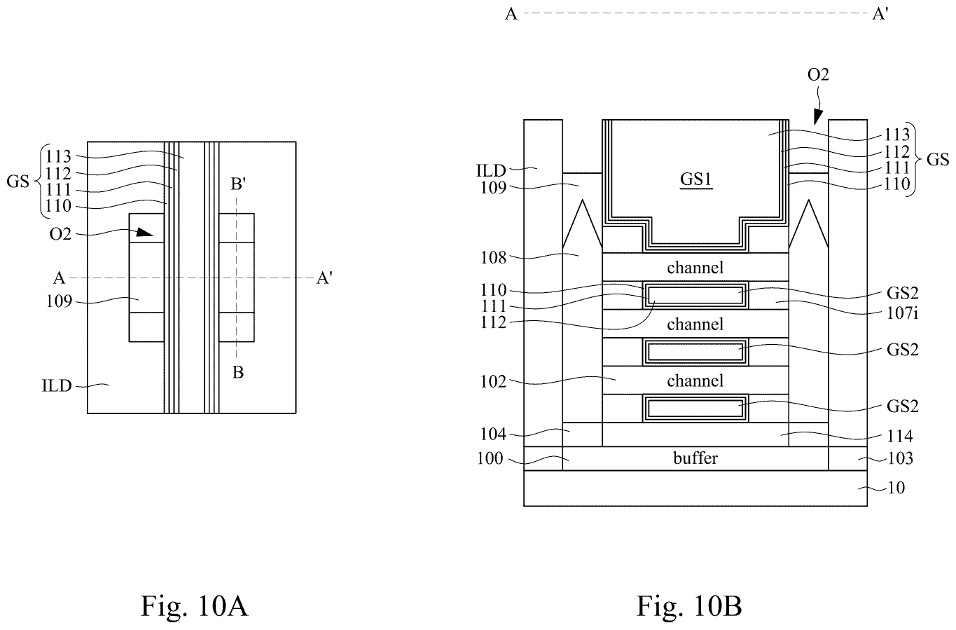

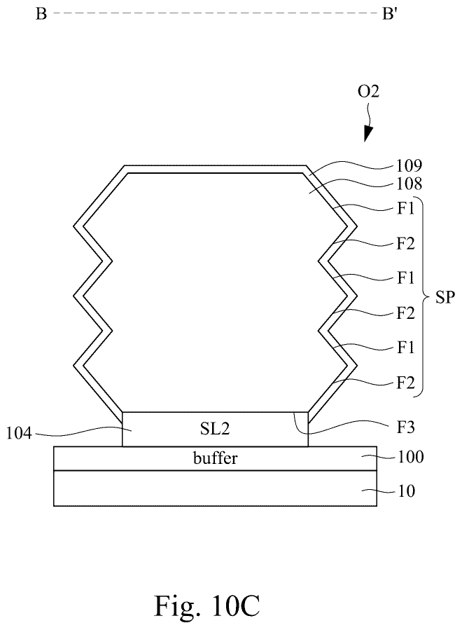

FIG. 10A is a top view of an intermediate stage in manufacturing of an IC structure, FIG. 10B is a cross-sectional view obtained from cut A-A′ in FIG. 10A, and FIG. 10C is a cross-sectional view obtained from cut B-B′ in FIG. 10A. In FIGS. 10A-10C, an etching process is performed on the interlayer dielectric layer ILD to form source/drain contact openings O2 extending through the interlayer dielectric layer ILD to expose the metal silicide layers 109 and the bottom sacrificial layers 104 below the epitaxial source/drain regions 108.

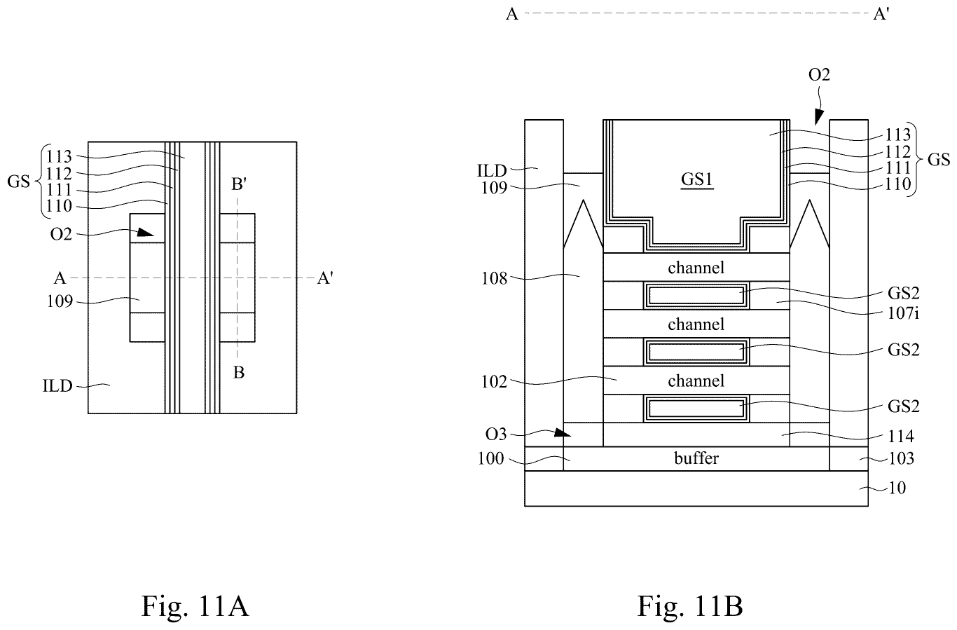

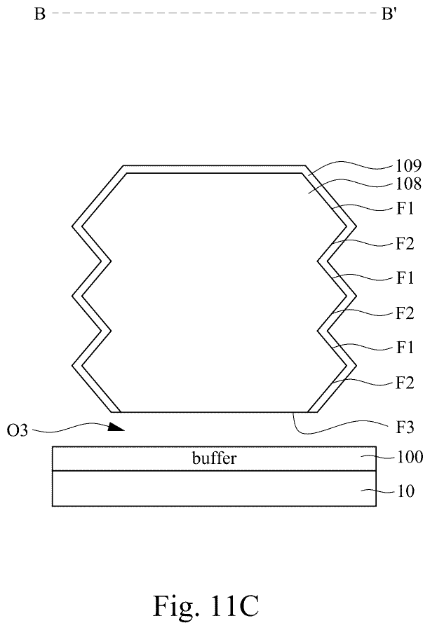

FIG. 11A is a top view of an intermediate stage in manufacturing of an IC structure, FIG. 11B is a cross-sectional view obtained from cut A-A′ in FIG. 11A, and FIG. 11C is a cross-sectional view obtained from cut B-B′ in FIG. 11A. In FIGS. 11A-11C, the bottom sacrificial layers 104 are removed by using a selective etching process that etches the material of the bottom sacrificial layers 104 (e.g., SiOCN) at a faster etch rate than etching other materials (e.g., metal silicide) exposed in the source/drain contact openings O2, thereby forming bottom openings O3 directly below the respective epitaxial source/drain regions 108, which allows for forming a source/drain contact metal to completely wrap around the epitaxial source/drain regions 108 in subsequent processing. In some embodiments, the bottom sacrificial layers 104 (e.g., SiOCN) can be selectively removed by using, for example, hydrofluoric acid (HF) and/or nitric acid (HNO₃).

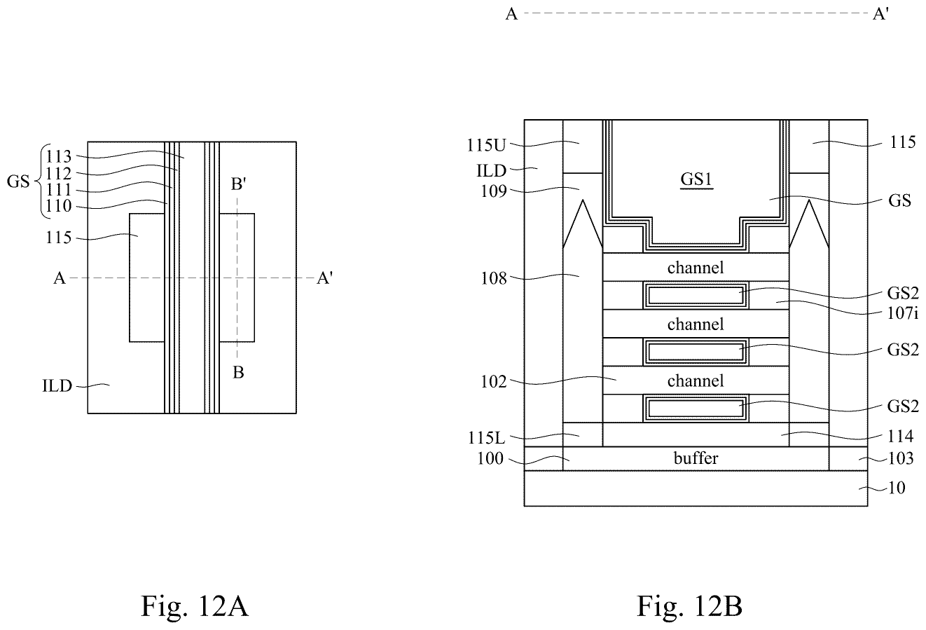

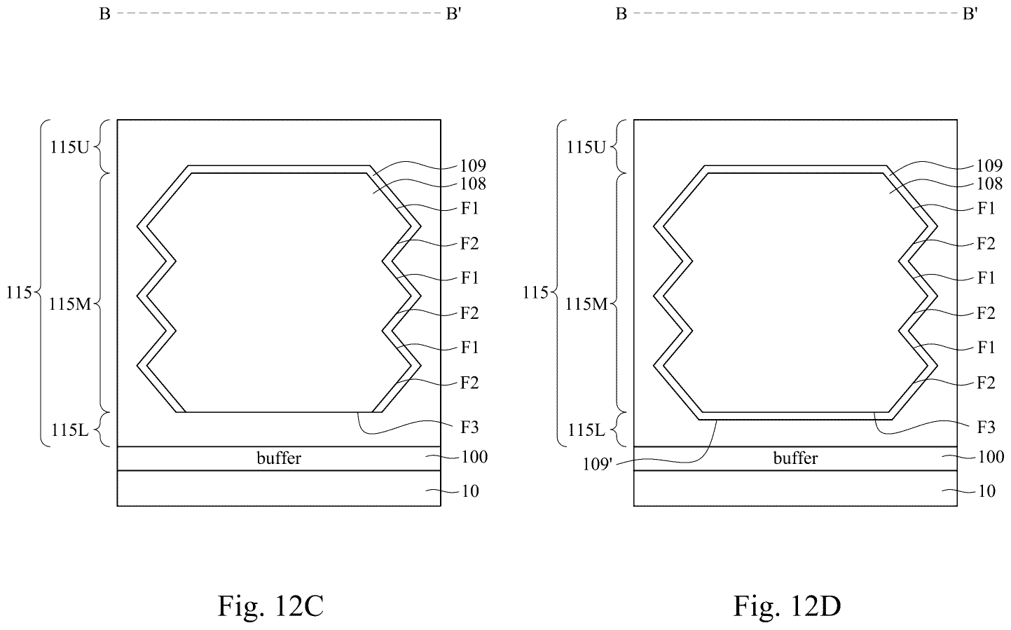

FIG. 12A is a top view of an intermediate stage in manufacturing of an IC structure, FIG. 12B is a cross-sectional view obtained from cut A-A′ in FIG. 12A, and FIG. 12C is a cross-sectional view obtained from cut B-B′ in FIG. 12A. In FIGS. 12A-12C, source/drain contacts 115 are formed in the source/drain contact openings O2 and the bottom openings O3. In some embodiments, the source/drain contacts 115 are formed by, for example, depositing one or more metal materials (e.g., Pt, Ti, TiN, Al, W, WN, Ru, RuO, Ta, Ni, Co, Cu, Ag, Au, the like or combinations thereof) overfilling the source/drain contact openings O2 and the bottom openings O3 by using suitable deposition techniques (e.g., CVD, PVD, ALD, the like or combinations thereof), and then performing a CMP process to remove excessive metal materials outside the source/drain contact openings O2.

Because removal of the bottom sacrificial layers 104 form bottom openings O3 below the epitaxial source/drain regions 108, the source/drain contacts 115 can be formed in the source/drain contact openings O2 as well as the bottom openings O3 to completely wrap around the epitaxial regions 108. In particular, as illustrated in FIG. 12C, a source/drain contact 115 includes a top contact portion 115 above the metal silicide layer 109, middle contact portions 115M level with and in contact with the zigzag-shaped sidewall profiles of the epitaxial source/drain region 108 and the metal silicide layer 109, and a bottom contact portion 115L below the epitaxial source/drain region 108 and the metal silicide layer 109. The middle contact portions 115M extend from the top contact portion 115U to the bottom contact portion 115L, and have a zigzag-shaped profile conformal to a zigzag-shaped sidewall profile of the epitaxial source/drain region 108. In particular, the middle contact portions 115M form zigzag-shaped interfaces with the metal silicide layer 109, and the zigzag-shaped interfaces are conformal to the zigzag-shaped sidewall profile of the epitaxial source/drain region 108. The bottom contact portion 115L overlaps and contacts an entirety of the bottom surface F3 of the epitaxial source/drain region 108. The top contact portion 115U overlaps and contacts an entirety of top surface of the metal silicide layer 109. In this way, the epitaxial source/drain region 108 can be completely enveloped in the source/drain contact 115, which in turn reduces the contact resistance.

FIG. 12D is a cross-sectional view obtained from cut B-B′ in FIG. 12A, in accordance with some other embodiments. The structure illustrated in FIG. 12D is generally the same as that illustrated in FIG. 12C, except that additional backside metal silicide layers 109′ are formed on the bottom surfaces F3 of the epitaxial source/drain regions 108 prior to forming the source/drain contact 115. In some embodiments, the metal silicide layer 109 and the underlying backside metal silicide layer 109′ collectively form a continuous metal silicide layer continuously wrapping around the top surface, the bottom surface, and opposite zigzag-shaped sidewalls of the epitaxial source/drain region 108. The backside metal silicide layer 109′ and the metal silicide layer 109 collectively wrap around the epitaxial source/drain region 108 completely, and the source/drain contact 115 wraps around the backside metal silicide layer 109′ and the metal silicide layer 109 completely, which in turn reduces the contact resistance.

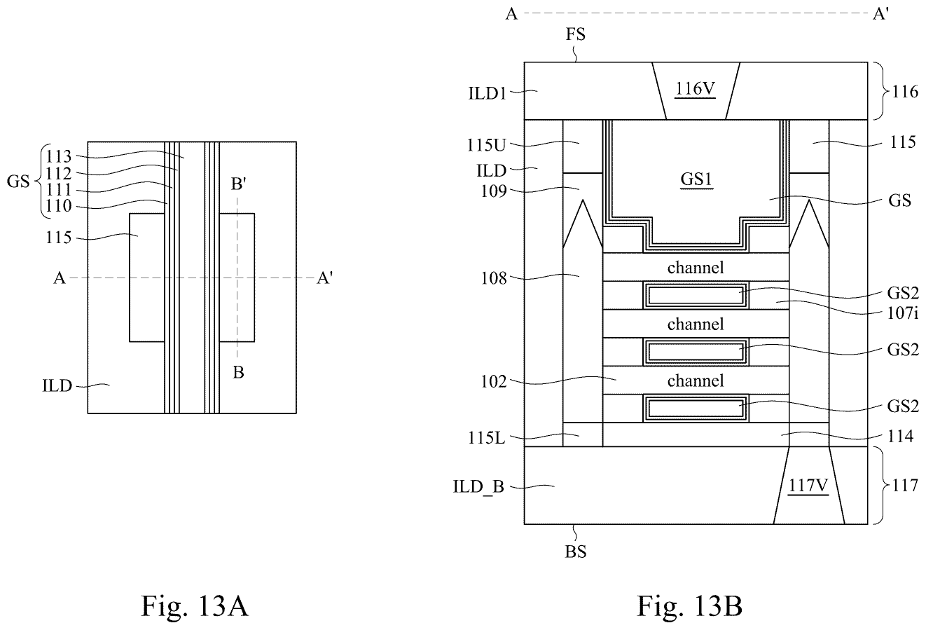

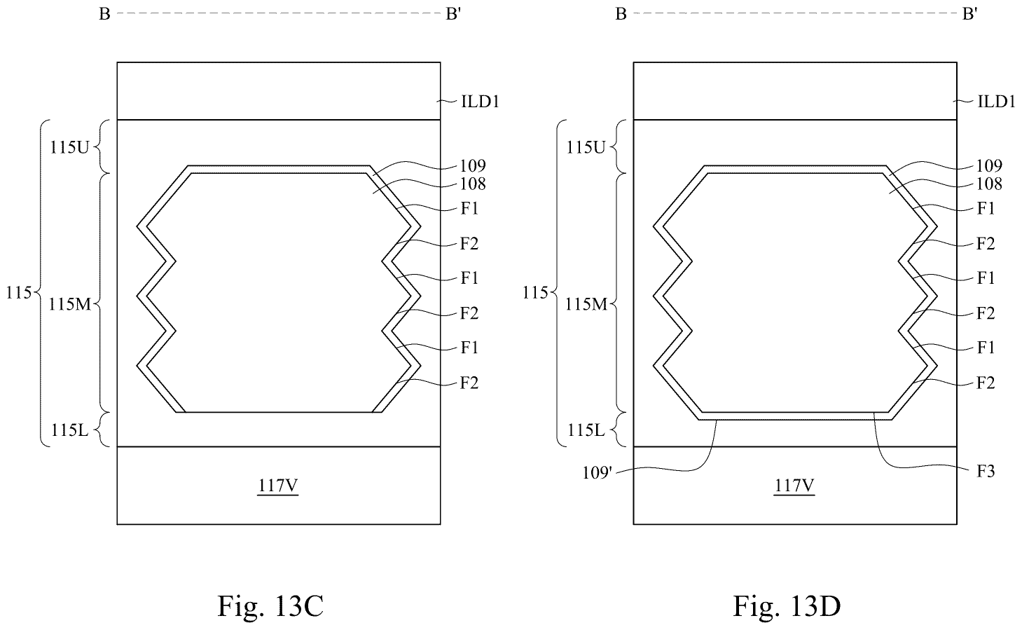

FIG. 13A is a plan view of an intermediate stage in manufacturing of an IC structure after forming a front-side interconnect structure 116 and a backside interconnect structure 117, FIG. 13B is a cross-sectional view obtained from cut A-A′ in FIG. 13A, and FIG. 13C is a cross-sectional view obtained from cut B-B′ in FIG. 13A. The plan view of FIG. 13A is zoomed to a level of gate structure GS for the sake of clearly indicating the cut A-A′ and cut B-B′, and thus the front-side interconnect structure illustrated in FIG. 13B is not shown in FIG. 13A. The front-side interconnect structure 116 may include one or more front-side interlayer dielectric layers ILD1 formed over the underlying interlayer dielectric layer ILD, and one or more metal interconnects, such as front-side vias 116V extending vertically in the interlayer dielectric layers ILD1.

In some embodiments, the front-side vias 116V can be formed using, for example, a single damascene process, a dual damascene process, the like, or combinations thereof. In some embodiments, the front-side interlayer dielectric layer ILD1 may include low-k dielectric materials having k values, for example, lower than about 4.0 or even 2.0 disposed between such conductive features. In some embodiments, the front-side interlayer dielectric layer ILD1 may be made of, for example, phosphosilicate glass (PSG), borophosphosilicate glass (BPSG), fluorosilicate glass (FSG), SiOₓC_{y}, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like. The front-side vias 116V may comprise metal materials such as W, Ru, Co, Cu, Ti, TiN, Ta, TaN, Mo, Ni, combinations thereof, or the like.

In some embodiments, after forming the front-side interconnect structure 116, a backside interconnect structure 117 is formed on a backside of the GAA transistor. For example, the substrate 10 and the buffer layer 100 can be removed by using, for example, a CMP process, a grinding process, or the like, such that the bottom contact portions 115L of the source/drain contacts 115 are exposed. Next, a backside interlayer dielectric layer ILD_B can be formed over the bottom contact portions 115L of the source/drain contacts 115, followed by forming a backside-via 117V in the backside interlayer dielectric layer ILD_B to contact a bottom contact portion 115L of a source/drain contact 115. In some embodiments, the backside via 117V is formed by, for example, etching a via hole extending vertically through the backside interlayer dielectric layer ILD_B, depositing one or more metal materials (e.g., Pt, Ti, TiN, Al, W, WN, Ru, RuO, Ta, Ni, Co, Cu, Ag, Au, the like or combinations thereof) overfilling the via hole by using suitable deposition techniques (e.g., CVD, PVD, ALD, the like or combinations thereof), and then performing a CMP process to remove excessive metal materials outside the via hole.

In FIG. 13B, the IC structure has a front-side surface FS and a backside surface BS opposite the front-side surface FS. In the illustrated embodiment, the front-side surface FS is top surface of the front-side interlayer dielectric layer ILD1, and the backside surface BS is the bottom surface of the backside interlayer dielectric layer ILD_B. Elements within the IC structure each have a front-side surface facing toward the front-side surface FS and a backside surface facing toward the backside surface BS. In some embodiments, the backside via 117V is in contact with a backside surface (i.e., bottom surface) of the source/drain contact 115 that fully wraps around the epitaxial source/drain region 108, which in turn reduces the contact resistance.

FIG. 13D is a cross-sectional view obtained from cut B-B′ in FIG. 13A, in accordance with some other embodiments. The structure illustrated in FIG. 13D is basically the same as that illustrated in FIG. 13C, except that backside metal silicide layers 109′ are formed on the bottom surfaces F3 of the epitaxial source/drain regions 108 prior to forming the source/drain contact 115, as discussed previously with respect to FIG. 12D.

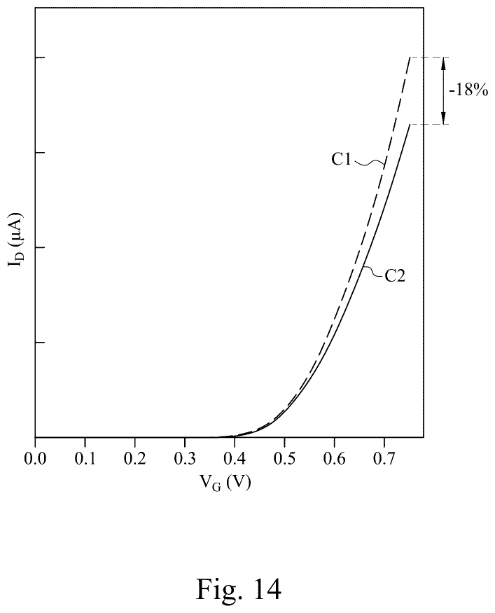

FIG. 14 is graph illustrating current-voltage (I-V) simulation results of transistors with different contact schemes. In FIG. 14, the drain current (ID) is plotted on the vertical axis and the gate voltage (VG) is plotted on the horizontal axis. The curve C1 represents an I-V characteristic of a transistor with a full-wraparound source/drain contact 115 coupled to a backside via 117V, as illustrated in FIGS. 13C-13D. In contrast, the curve C2 represents an I-V characteristic of a transistor coupled to the backside via 117V without the full-wraparound source/drain contact 115. The comparative analysis based on the curve C1 and C2 reveals that the transistor with the full-wraparound source/drain contact 115 exhibits an improved drain current performance, indicative of a reduction in contact resistance. This improvement can be quantitatively supported by the observation that the drain current decreases by about 18% in the absence of full-wraparound source/drain contact 115.

In the foregoing embodiments, the IC structure includes GAA transistors with the full-wraparound source/drain contact. However, in some other embodiments, planar transistors, FinFETs, nanowire-FETs or complementary field effect transistors (CFETs) can also formed with the full-wraparound source/drain contact. Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the full-wraparound contact can increase contact area, which in turn reduces the source/drain contact resistance and hence increases the transistor's on-current.

In some embodiments, a method comprises forming a bottom sacrificial layer over a substrate, forming an epitaxial structure over the bottom sacrificial layer, etching the epitaxial structure such that the bottom sacrificial layer is exposed, forming an epitaxial source/drain region on the exposed bottom sacrificial layer, removing the bottom sacrificial layer from a bottom surface of the epitaxial source/drain region, and after removing the bottom sacrificial layer, forming a source/drain contact wrapping around the bottom surface, a top surface, and opposite sidewalls of the epitaxial source/drain region. In some embodiments, the method further comprises forming a silicide layer over the epitaxial source/drain region prior to forming the source/drain contact. In some embodiments, the source/drain contact wraps around the silicide layer. In some embodiments, the source/drain contact has a bottom surface lower than a bottom end of the silicide layer. In some embodiments, the method further comprises forming a backside via having a top end in contact with a bottom surface of the source/drain contact. In some embodiments, the method further comprises forming a silicide layer on a bottom surface of the epitaxial source/drain region prior to forming the source/drain contact. In some embodiments, the epitaxial source/drain region is in contact with a bottom surface of the silicide layer. In some embodiments, the epitaxial structure comprises a plurality of first semiconductor layers and a plurality of second semiconductor layers alternating with the plurality of first semiconductor layers, and the bottom sacrificial layer is formed of a material different from the plurality of first semiconductor layers and the plurality of second semiconductor layers. In some embodiments, the method further comprises removing the plurality of first semiconductor layers, and forming a gate structure wrapping around the plurality of second semiconductor layers. In some embodiments, the bottom sacrificial layer has a thickness greater than a thickness of one of the plurality of first semiconductor layers and the plurality of second semiconductor layers. In some embodiments, the bottom sacrificial layer is formed of silicon oxycarbon nitride (SiOCN).

In some embodiments, a method comprises forming an epitaxial stack comprising a plurality of channel layers over a substrate, forming epitaxial source/drain regions at opposite sides of the epitaxial stack, forming a gate structure wrapping around each of the plurality of channel layers, forming a gate structure wrapping around each of the plurality of channel layers, and forming a source/drain contact over a first one of the epitaxial source/drain regions. The source/drain contact extends from above a top surface of the first one of the epitaxial source/drain regions to below a bottom surface of the first one of the epitaxial source/drain regions. In some embodiments, the source/drain contact overlaps with an entirety of the bottom surface of the first one of the epitaxial source/drain regions. In some embodiments, the source/drain contact overlaps with an entirety of the top surface of the first one of the epitaxial source/drain regions. In some embodiments, the source/drain contact has a zigzag-shaped profile conformal to a zigzag-shaped sidewall profile of the first one of the epitaxial source/drain regions. In some embodiments, the method further comprises forming a backside via below a bottom surface of the source/drain contact.

In some embodiments, a device comprises a gate structure, epitaxial source/drain regions on opposite sides of the gate structure, a first source/drain contact wrapping around a top surface, a bottom surface, and opposite sides of a first one of the epitaxial source/drain regions, and a backside via below the first one of the epitaxial source/drain regions. The backside via is in contact with a bottom surface of the first source/drain contact. In some embodiments, the device further comprises a second source/drain contact wrapping around a top surface, a bottom surface, and opposite sides of a second one of the epitaxial source/drain regions. In some embodiments, the device further comprises a silicide layer in contact with the top surface, the bottom surface, and the opposite sides of the first one of the epitaxial source/drain regions. In some embodiments, the first source/drain contact forms a zigzag-shaped interface with the silicide layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a bottom sacrificial layer over a substrate;
forming an epitaxial structure over the bottom sacrificial layer;
etching the epitaxial structure such that the bottom sacrificial layer is exposed;
forming an epitaxial source/drain region on the exposed bottom sacrificial layer;
removing the bottom sacrificial layer from a bottom surface of the epitaxial source/drain region; and
after removing the bottom sacrificial layer, forming a source/drain contact wrapping around the bottom surface, a top surface, and opposite sidewalls of the epitaxial source/drain region.

2. The method of claim 1, further comprising:
forming a silicide layer over the epitaxial source/drain region prior to forming the source/drain contact.

3. The method of claim 2, wherein the source/drain contact wraps around the silicide layer.

4. The method of claim 2, wherein the source/drain contact has a bottom surface lower than a bottom end of the silicide layer.

5. The method of claim 1, further comprising:
forming a backside via having a top end in contact with a bottom surface of the source/drain contact.

6. The method of claim 1, further comprising:
forming a silicide layer on a bottom surface of the epitaxial source/drain region prior to forming the source/drain contact.

7. The method of claim 6, wherein the epitaxial source/drain region is in contact with a bottom surface of the silicide layer.

8. The method of claim 1, wherein the epitaxial structure comprises a plurality of first semiconductor layers and a plurality of second semiconductor layers alternating with the plurality of first semiconductor layers, and the bottom sacrificial layer is formed of a material different from the plurality of first semiconductor layers and the plurality of second semiconductor layers.

9. The method of claim 8, further comprising:
removing the plurality of first semiconductor layers; and
forming a gate structure wrapping around the plurality of second semiconductor layers.

10. The method of claim 8, wherein the bottom sacrificial layer has a thickness greater than a thickness of one of the plurality of first semiconductor layers and the plurality of second semiconductor layers.

11. The method of claim 1, wherein the bottom sacrificial layer is formed of silicon oxycarbon nitride (SiOCN).

12. A method comprising:
forming an epitaxial stack over a substrate, the epitaxial stack comprising a plurality of channel layers;
forming epitaxial source/drain regions at opposite sides of the epitaxial stack;
forming a gate structure wrapping around each of the plurality of channel layers; and
forming a source/drain contact over a first one of the epitaxial source/drain regions, the source/drain contact extending from above a top surface of the first one of the epitaxial source/drain regions to below a bottom surface of the first one of the epitaxial source/drain regions.

13. The method of claim 12, wherein the source/drain contact overlaps with an entirety of the bottom surface of the first one of the epitaxial source/drain regions.

14. The method of claim 12, wherein the source/drain contact overlaps with an entirety of the top surface of the first one of the epitaxial source/drain regions.

15. The method of claim 12, wherein the source/drain contact has a zigzag-shaped profile conformal to a zigzag-shaped sidewall profile of the first one of the epitaxial source/drain regions.

16. The method of claim 12, further comprising:
forming a backside via below a bottom surface of the source/drain contact.

17. A device comprising:
a gate structure;
epitaxial source/drain regions on opposite sides of the gate structure;
a first source/drain contact wrapping around a top surface, a bottom surface, and opposite sides of a first one of the epitaxial source/drain regions; and
a backside via below the first one of the epitaxial source/drain regions, the backside via being in contact with a bottom surface of the first source/drain contact.

18. The device of claim 17, further comprising:
a second source/drain contact wrapping around a top surface, a bottom surface, and opposite sides of a second one of the epitaxial source/drain regions.

19. The device of claim 17, further comprising:
a silicide layer in contact with the top surface, the bottom surface, and the opposite sides of the first one of the epitaxial source/drain regions.

20. The device of claim 19, wherein the first source/drain contact forms a zigzag-shaped interface with the silicide layer.
